(19) United States
(12) Patent Application Publication
(10) Pub. No.: US 2019/0241429 A1
(43) Pub. Date: Aug. 8, 2019

(54) Hybrid Galvanic Connection System for a MEMS Sensor Device Package

(71) Applicant: Robert Bosch GmbH, Stuttgart (DE)

(72) Inventor: Mikko VA Suvanto, Kangasala (FI)

(21) Appl. No.: 16/315,632

(22) PCT Filed: Jul. 10, 2017
(86) PCT No.: PCT/EP2017/067194

§ 371 Date: Jan. 5, 2019

Related U.S. Application Data
(60) Provisional application No. 62/360,100, filed on Jul. 8, 2016.

(51) Int. Cl. B81C 1/00; B81B 7/02; B81B 7/00

(52) U.S. Cl. CPC B81C 1/0023; B81B 7/02; B81C 2203/0792; B81B 2201/0257; B81B 7/0032

(57) ABSTRACT

A MEMS sensor device package comprises a sensor assembly comprising a sensor device and a sensor circuit communicating coupled to the sensor device, The MEMS sensor device package further comprises an assembly package housing having a top member and a bottom member attached to the top member for encapsulating the sensor assembly. A hybrid galvanic connection system is provided to couple the sensor device to the sensor circuit.

### FIELD

The disclosure generally relates to microelectromechanical system (MEMS) packages, and more particularly, to a MEMS sensor device package having a hybrid galvanic connection system.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

Embodiments of the disclosure related to a MEMS sensor device package having a hybrid galvanic connection system is provided. The package includes a sensor assembly comprising a sensor device and a sensor circuit communicating coupled to the sensor device. A package housing comprising a top member and a bottom member attached to the top member for encapsulating the sensor assembly. A hybrid galvanic connection system is provided to couple the sensor device to the sensor circuit. The hybrid galvanic connection system comprises a wire bonding connection and a flip-chip connection.

According to another aspect of the disclosure, a computer readable medium having computer-executable instructions for performing a method of selectively transmitting a set of data from at least one of a microphone or a sensor circuit includes identifying a first data from at least one of a microphone or a sensor circuit and identifying a second data from at least one of a microphone or a sensor circuit, wherein each data comprising at least one of a signal strength or a data transmission speed. The computer readable medium further includes a processor for directing at least one of the microphone or the sensor circuit to transmit at least one of the first and second data. The processor may be integrated into either the microphone or the sensor circuit. Alternatively, the processor may be remotely coupled to at least one of the microphone or the sensor circuit. A package is provided to encapsulate the microphone and sensor circuit. The processor to direct the first and second data is either contained in the package or located outside the package and further is communicatively coupled the microphone to the sensor circuit.

According to another aspect of the disclosure, a hybrid galvanic connection system for a microphone device includes a wire bonding for transmitting first data from at least one of a microphone or a sensor circuit and a flip-chip connection for transmitting the second data. The first data has a perimeter lower than a perimeter of the second data, wherein the perimeter can be either signal strength or data transmission speed. The hybrid galvanic connection system further includes a processor for directing at least one of the microphone or the sensor circuit to transmit at least one of the first and second data. The processor may be integrated into either the microphone or the sensor circuit. Alternatively, the processor may be remotely coupled to at least one of the microphone or the sensor circuit. A package is provided to encapsulate the microphone and sensor circuit. The processor to direct the first and second data is either contained in the package or located outside the package and further is communicatively coupled the microphone to the sensor circuit.

According to another aspect of the disclosure, a MEMS sensor device package includes a package housing including a top member and a bottom member coupled to the top member forming a cavity, a sensor device coupled to the bottom member within the cavity, a sensor circuit, and a hybrid galvanic connection system connected between the sensor device and the sensor circuit, the hybrid galvanic connection system electrically connected to the bottom member, the hybrid galvanic connection system having a top surface, wherein the sensor device and the sensor circuit are electrically connected to the top surface of the hybrid galvanic connection system. The hybrid galvanic connection system comprises a wire bonding connection and a flip-chip connection. The flip-chip connection formed within the bottom member and electrically connected to the bottom member, the flip-chip connection having the top surface being electrically connected between the sensor device and the sensor circuit. The flip-chip connection is selected from a material consisting of Au, Ni, Sn, SnAg, SnAu, Pb, and SnPb. The wire bonding connection formed above the bottom member and electrically connected between the sensor device and the sensor circuit. Each of the sensor device and the sensor circuit having an upper portion and a lower portion, the wire bonding connection electrically connecting the upper portion of the sensor device and the upper portion of the sensor circuit with the lower portion of the sensor device and the lower portion of the sensor circuit.

### BRIEF DESCRIPTION OF THE DRAWINGS

These and other features, aspects, and advantages of this disclosure will become better understood when the following detailed description of certain exemplary embodiments is read with reference to the accompanying drawings in which like characters represent like arts throughout the drawings, wherein:

FIG. 1 is a perspective view of a MEMS sensor device package in accordance with embodiments of a disclosure;

FIG. 2 is a cross-sectional view of an exemplary MEMS sensor device package in accordance with a described embodiment of the disclosure; and

FIG. 3 is a block diagram of the MEMS sensor device package of FIG. 2 in accordance with a described embodiment of the disclosure.

### DETAILED DESCRIPTION

The following description is presented to enable any person skilled in the art to make and use the described embodiments, and is provided in the context of a particular application and its requirements. Various modifications to the described embodiments will be readily apparent to those skilled in the art, and the general principles defined herein may be applied to other embodiments and applications without departing from the spirit and scope of the described embodiments. Thus, the described embodiments are not limited to the embodiments shown, but are to be accorded the widest scope consistent with the principles and features disclosed herein.

The disclosure is a sensor device package with a hybrid galvanic connection system. The sensor device package includes a package housing or an enclosure for housing one or more sensor devices, internal components, or combination thereof. The sensor devices may be such as MEMS transducers, speakers, receivers, microphones, pressure sensors, thermal sensors, optical sensors, imaging sensors, chemical sensors, gyroscopes, inertial sensors, humidity sensors, accelerometers, gas sensors, environmental sensors, motion sensors, navigation sensors, vital sensors, tunnel magnetoresistive (TMR) sensors, proximity sensors, bolometers, or combination thereof. The microphones may be electret microphones, capacitive microphones, piezoelectric microphones, silicon microphones, optical microphones, or any suitable acoustic microphones. The sensor device package is integrated into a client machine. Other electronic components, such as sensor devices, speakers, graphical processor units, computer processor units, and any suitable computer implemented devices may be disposed either in the sensor device package, in the client machine, or coupled to the sensor device package integrated into the client machine. The client machine may be a personal computer or desktop computer, a laptop, a cellular or smart phone, a tablet, a personal digital assistant (PDA), a gaming console, an audio device, a video device, an entertainment device such as a television, a vehicle infotainment, a wearable device, an entertainment or infotainment remote control, a thin client system, a thick client system, or the like.

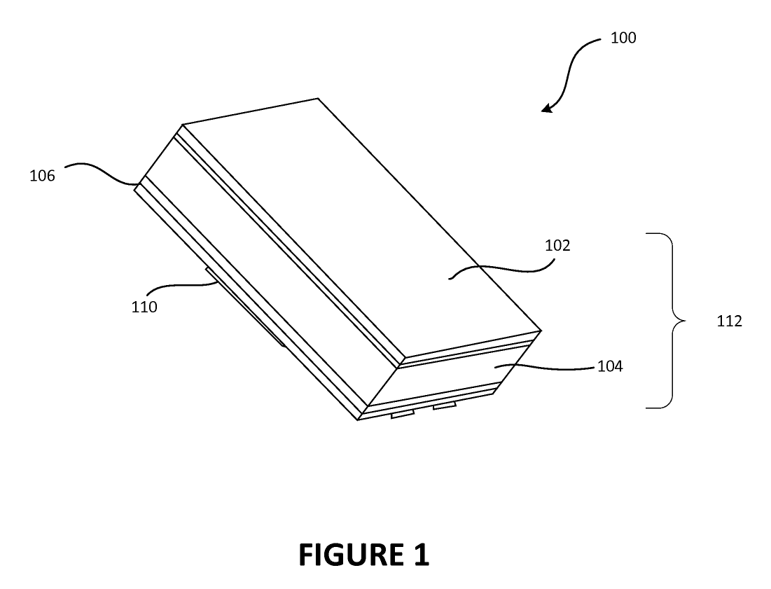

FIG. 1 is a perspective of a MEMS sensor device package 100 according to an exemplary embodiment of the disclosure. The MEMS sensor device package 100 includes a package housing 112 having a lid 102, a spacer 104, and a substrate 106 attached to the spacer 104 by any suitable methods of attachment. More than one sensor device and/or internal component may be housed within the MEMS sensor device package 100. The sensor devices may be MEMS transducers, speakers, receivers, microphones, pressure sensors, thermal sensors, optical sensors, imaging sensors, chemical sensors, gyroscopes, humidity sensors, inertial sensors, vital sensors, TMR sensors, accelerometers, gas sensors, environmental sensors, motion sensors, navigation sensors, proximity sensors, bolometers, or combination thereof. The internal components may be integrated circuits, ASICs, processors, controllers, energy storage devices, sensor circuits, and any suitable components. Depending on the application, an opening such as a port, a vent, or a passageway for receiving attributes from an environment which the package 100 is exposed may be formed on the sensor device package 100 by etching, drilling, punching, or any suitable methods. The attributes may be acoustic signal, pressure signal, optical signal, gas signal, and any suitable signal. Although the MEMS sensor device package 100 as depicted comprises a multi-structure package housing 112, various aspects and configurations either in a single structure package housing, a two piece structure package housing, or multi-structure package housing may be used to encapsulate at least one internal component. As an example, the lid 102 and the spacer 104 may be formed as a single structure, defines a cover or a cap. One or more bonding pads 110 may be formed on at least one of the substrate 106 or the cover by any suitable method for mounting the sensor device package 100 to an external printed circuit board or another support member of the client machine. In some embodiments, the package housing further includes an interposer coupled the cover 102 to either the spacer 104 or the substrate 106. The sensor circuit 114, the MEMS sensor device 116, or combination thereof disposed within the package housing 112 may be mounted to any of the cover 102, the spacer 104, the interposer, or the substrate 106 by any suitable method of attachments.

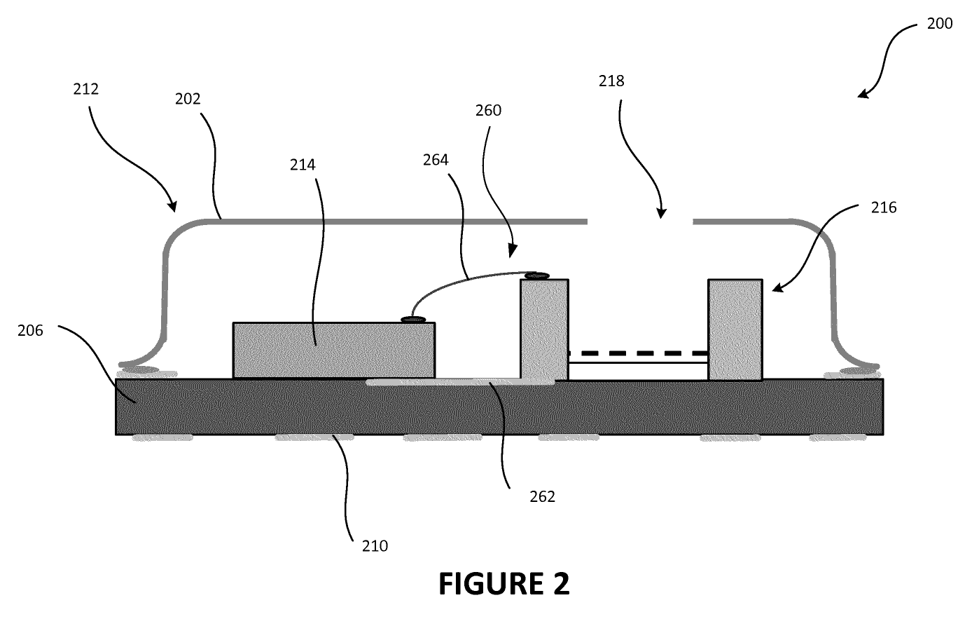

FIG. 2 is a cross-sectional view of an exemplary MEMS sensor device package 200 utilizing at least one sensor circuit 214 and a MEMS sensor device 216 in accordance with a described embodiment of the disclosure. The MEMS sensor device package 200 is similar to the MEMS sensor device package 100 depicted in FIG. 1. The MEMS device package 200 comprises a package housing 212 having a top member 202 and a bottom member 206 coupled to the top member 202 by any suitable method of attachments. Disposed within the package housing 212 are the sensor circuit 214 and the MEMS sensor device 216 coupled to each other via a hybrid galvanic connection system 260. In some embodiments, more than one MEMS sensor device 216 coupled to the sensor circuit 214 may be disposed within the package housing 212. In another embodiments, more than one sensor circuit 214 is coupled to the sensor circuit 214 which are disclosed within the package housing. In yet embodiments, more than one MEMS sensor device 216 without the sensor circuit 214 may be disposed within the package housing. In further yet embodiment, the sensor circuit 214 and the MEMS sensor device 216 disposed within the package housing 212 may share a common cavity or a common chamber defined by the package housing 212. In another embodiment, a dividing wall is provided to separate the package housing 212 into two cavities or chambers, each of the sensor circuit 214 and the MEMS sensor device 216 are disposed in separate cavities or chambers. The package housing 212 further includes bonding pads 210 formed on the bottom member 206 by any suitable methods of attachment which in turn coupled the package housing 212 to an external assembly or circuitry of a client machine. Signal generated by the sensor circuit 214 and the MEMS sensor device 216 is transmitted externally via the hybrid galvanic connection system 260 and the bonding pad 210 to the external assembly or external circuitry. Although the sensor circuit 214 and the MEMS sensor device 216 as illustrated are mounted to the package housing 212 on a side-by-side configuration, other mounting configurations are possible, depending on the application. Other possible mounting configurations include back-to-back configuration, stacked configuration, etc. As an example, the MEMS sensor device 216 may be mounted either on top of the sensor circuit 214 or to the bottom of the sensor circuit 214, define a stacked configuration. As another example, the sensor circuit 214 includes a cavity and the MEMS sensor device 216 is disposed within the cavity and thereby is surrounded by the sensor circuit 214. Together, the sensor circuit 214 and the MEMS sensor device 216 are mounted to the same side of the wall of the package housing 212. As yet another example, the sensor circuit 214 and the MEMS sensor device 216 mounted within the package housing 212 may be mounted on different walls of the package housing 212 such that the sensor circuit 214 and the MEMS sensor device 216 are positioned opposite from each other which defined as back-to-back configuration. In some embodiments, instead of back-to-back configuration, the sensor circuit 214 and the MEMS sensor device 216 mounted to different walls of the package housing 212 are positioned in proximal relationship to each other.

As previously described, the sensor circuit 214 and the MEMS sensor device 216 may be mounted to any portion of the package housing 21, depending on the application. In one embodiment, the sensor circuit 214 is mounted to the top member 202 whereas the MEMS sensor device 216 is mounted to either the bottom member 206 or the spacer 204. In another embodiment, the sensor circuit 214 is mounted to the spacer 204 whereas the MEMS sensor device 216 is mounted to either the top member 202 or the bottom member 206. In yet further embodiment, any sensor circuit 214 and/or MEMS sensor device 216 may be mounted to either the bottom member 206 or the spacer 204 of the package housing 212, depending on the application. As illustrated, the sensor circuit 214 and the MEMS sensor device 216 are mounted to the bottom member 206 of the package housing 212. The top member 202 may be a lid or a cap and the bottom members 206 may be a substrate. As illustrated, the top member 202 is a lid and the bottom member 206 is a substrate. In some embodiment, the bottom member 206 may be an interposer. In yet another embodiment, the bottom member 206 may include a substrate with integrated interposer. Depending on the applications, more than one MEMS sensor device 216 and sensor circuit 214 may be encapsulated in the package housing 212.

The MEMS sensor device package 200 further includes an opening 216 formed on the lid 202 for receiving attributes from an environment to enter the package housing 212. The attributes may be acoustic signal, thermal signal, pressure signal, optical signal, gas signal, and any suitable signal. The opening 216 may be formed by etching, drilling, punching, or any suitable methods in a single or multiple lid fabrication processes. In some embodiments, the opening may be formed on the bottom member 206. Although one opening 216 is provided, more than one opening 216 may be formed on the package housing 212. An optional environmental bather may be provided within the opening 216 to prevent debris and moisture to enter the package housing 212. The environmental bather may be a mesh, a thin film with a plurality of perforated holes, or another suitable elements, depending on the applications. The hybrid galvanic connection system 260 includes a wire bonding connection 264 for coupling the sensor circuit 214 to the MEMS sensor device 216. As illustrated, the sensor circuit 214 and the MEMS sensor device 216 are flip-chip mounted onto the bottom member 206 and are connected to each other by for example a solder bump, a micro-solder bump, a solder pad, or the like, in any number of quantity, defines a flip-chip connection 262. Since flip-chip connection 262 is configured to handle high speed transmission level, MEMS control signals may be transmitted through the flip-chip connection 262. The flip-chip connection 262 is formed from material such as Au, Ni, Sn, SnAg, SnAu, Pb, SnPb, or any suitable materials, depending on the applications. Wire bonding connection 264 is configured to handle leak critical signals such as impedance/leak critical MEMS sensor device signals.

Alternatively, a MEMS sensor device package includes a package housing including a top member and a bottom member coupled to the top member forming a cavity, a sensor device coupled to the bottom member within the cavity, a sensor circuit, and a hybrid galvanic connection system connected between the sensor device and the sensor circuit, the hybrid galvanic connection system electrically connected to the bottom member, the hybrid galvanic connection system having a top surface, wherein the sensor device and the sensor circuit are electrically connected to the top surface of the hybrid galvanic connection system. The hybrid galvanic connection system comprises a wire bonding connection and a flip-chip connection. The flip-chip connection formed within the bottom member and electrically connected to the bottom member, the flip-chip connection having the top surface being electrically connected between the sensor device and the sensor circuit. The flip-chip connection is selected from a material consisting of Au, Ni, Sn, SnAg, SnAu, Pb, and SnPb. The wire bonding connection formed above the bottom member and electrically connected between the sensor device and the sensor circuit. Each of the sensor device and the sensor circuit having an upper portion and a lower portion, the wire bonding connection electrically connecting the upper portion of the sensor device and the upper portion of the sensor circuit with the lower portion of the sensor device and the lower portion of the sensor circuit.

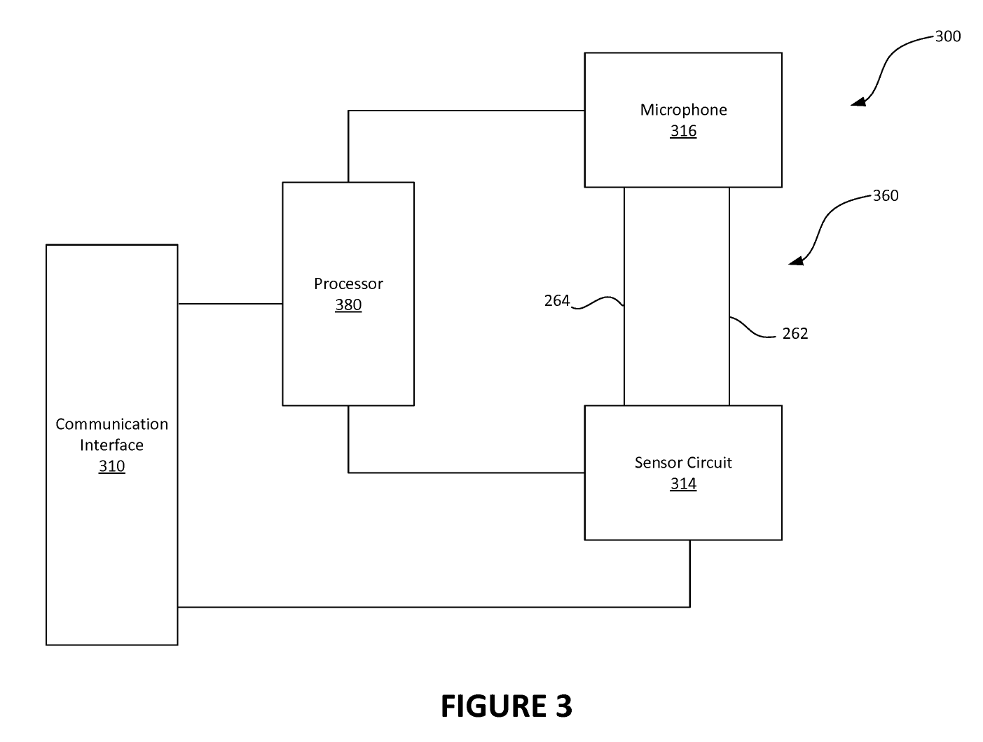

FIG. 3 is a block diagram illustrating a MEMS microphone system 300 comprises a microphone sensor or an acoustic transducer 316 and a sensor circuit 314 coupled to the microphone sensor 316 via a galvanic connection system 360. A computer module such as a processor 380 or a communication interface 310 may be optionally connected to at least one of the microphone sensor 316 or the sensor circuit 314. A package housing comprises a chamber for encapsulating the microphone sensor 316, the sensor circuit 314, and the galvanic connection system 360. The communication interface 310 may either contained within the chamber or located outside the package housing. The galvanic connection system 360 comprises a flip-chip connection 262 for transmitting the second data and a wire bonding connection 264 for transmitting first data from at least one of the microphone sensor 316 or the sensor circuit 314. The first data has a perimeter lower than a perimeter of the second data, wherein the perimeter can be either signal strength or data transmission speed. The processor for directing at least one of the microphone sensor 316 or the sensor circuit 314 to transmit at least one of the first and second data may be integrated into either the microphone sensor 316 or the sensor circuit 314. Alternatively, the processor may be remotely coupled to at least one of the microphone sensor 316 or the sensor circuit 314.

Alternatively, a computer readable medium having computer-executable instructions for performing a method of selectively transmitting a set of data from at least one of a microphone or a sensor circuit includes identifying a first data from at least one of a microphone or a sensor circuit and identifying a second data from at least one of a microphone or a sensor circuit, wherein each data comprising at least one of a signal strength or a data transmission speed. The computer readable medium further includes a processor for directing at least one of the microphone or the sensor circuit to transmit at least one of the first and second data. The processor may be integrated into either the microphone or the sensor circuit. Alternatively, the processor may be remotely coupled to at least one of the microphone or the sensor circuit. A package is provided to encapsulate the microphone and sensor circuit. The processor to direct the first and second data is either contained in the package or located outside the package and further is communicatively coupled the microphone to the sensor circuit

The embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling with the sprit and scope of this disclosure.

While the patent has been described with reference to various embodiments, it will be understood that these embodiments are illustrative and that the scope of the disclosure is not limited to them. Many variations, modifications, additions, and improvements are possible. More generally, embodiments in accordance with the patent have been described in the context or particular embodiments. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A MEMS sensor device package comprising:
a sensor assembly comprising a sensor device and a sensor circuit;
a package housing comprising a top member and a bottom member attached to the top member for encapsulating the sensor assembly; and
a hybrid galvanic connection system electrically connected between the sensor device and the sensor circuit, the hybrid galvanic connection system having a top surface formed within the bottom member and electrically connected to the bottom member.

2. The MEMS sensor device package of claim 1 wherein the hybrid galvanic connection system comprises a wire bonding connection and a flip-chip connection.

3. The MEMS sensor device package of claim 2 wherein the flip-chip connection formed within the bottom member and electrically connected to the bottom member, flip-chip connection having the top surface being electrically connected between the sensor device and the sensor circuit.

4. The MEMS sensor device package of claim 3 wherein the flip-chip connection is selected from a material consisting of Au, Ni, Sn, SnAg, SnAu, Pb, and SnPb.

5. The MEMS sensor device package of claim 2 wherein the wire bonding connection formed above the bottom member and electrically connected between the sensor device and the sensor circuit.

6. The MEMS sensor device package of claim 5 wherein each of the sensor device and the sensor circuit having an upper portion and a lower portion, the wire bonding connection electrically connecting the upper portion of the sensor device and the upper portion of the sensor circuit with the lower portion of the sensor device and the lower portion of the sensor circuit.

7. A computer readable medium having computer-executable instructions for performing a method of selectively transmitting a set of data from at least one of a microphone or a sensor circuit comprising:
identifying a first data from at least one of a microphone or a sensor circuit; and
identifying a second data from at least one of a microphone or a sensor circuit;
wherein each data comprising at least one of a signal strength or a data transmission speed.

8. The computer readable medium of claim 7 further comprising a processor for directing at least one of the microphone or the sensor circuit to transmit at least one of the first and second data via the hybrid galvanic connection system.

9. The computer readable medium of claim 8 wherein the processor is contained within a package housing forming a chamber for encapsulating the microphone and the sensor circuit.

10. The computer readable medium of claim 8 wherein the processor is remotely coupled to at least one of the microphone or the sensor circuit.

11. A MEMS sensor package comprising:
a package housing including a top member and a bottom member coupled to the top member forming a cavity;
a sensor device coupled to the bottom member within the cavity;
a sensor circuit; and
a hybrid galvanic connection system connected between the sensor device and the sensor circuit, the hybrid galvanic connection system electrically connected to the bottom member, the hybrid galvanic connection system having a top surface;
wherein the sensor device and the sensor circuit are electrically connected to the top surface of the hybrid galvanic connection system.

12. The MEMS sensor package of claim 11 wherein the hybrid galvanic connection system comprises a wire bonding connection and a flip-chip connection.

13. The MEMS sensor device package of claim 12 wherein the flip-chip connection formed within the bottom member and electrically connected to the bottom member, the flip-chip connection having the top surface being electrically connected between the sensor device and the sensor circuit.

14. The MEMS sensor device package of claim 13 wherein the flip-chip connection is selected from a material consisting of Au, Ni, Sn, SnAg, SnAu, Pb, and SnPb.

15. The MEMS sensor device package of claim 12 wherein the wire bonding connection formed above the bottom member and electrically connected between the sensor device and the sensor circuit.

16. The MEMS sensor device package of claim 15 wherein each of the sensor device and the sensor circuit having an upper portion and a lower portion, the wire bonding connection electrically connecting the upper portion of the sensor device and the upper portion of the sensor circuit with the lower portion of the sensor device and the lower portion of the sensor circuit.
